(19) United States
(12) Patent Application Publication
(10) Pub. No.: US 2012/0044009 A1
(43) Pub. Date: Feb. 23, 2012

(54) Level-Shifting Latch

(76) Inventor: Greg M. Hess, Mountain View, CA (US)

(21) Appl. No.: 12/859,919

(22) Filed: Aug. 20, 2010

(51) Int. Cl. H03L 5/00

(52) U.S. Cl. 327/333

(57) ABSTRACT

A level-shifting latch circuit is disclosed. The level-shifting latch circuit may provide a level-shifting function, a data state retention function, and a dynamic-to-static conversion function. The level-shifting latch may receive two input signals from a dynamic logic circuit that are driven to the same state during a precharge phase. During an evaluation phase, one of the input signals may evaluate to a logic state complementary to the other input. The level-shifting latch circuit may generate an output signal corresponding to the input signal. On a precharge phase of a next cycle, the level-shifting latch may retain the state of the output when the two inputs are again driven to the same state.

### BACKGROUND

1. Field of the Invention

This invention relates to electronic circuits, and more particularly, to level-shifting circuits and latch circuits.

2. Description of the Related Art

Many integrated circuits (IC's) include circuits that operate according to a supply voltage that is different than other circuits also implemented on the same IC die. In many cases, it is necessary for circuitry operating in one power domain (operating at a first supply voltage) to communicate with circuitry operating in another power domain (operating at a second supply voltage different from the first). In such cases, level-shifter circuits may be used to couple the circuitry in one power domain to circuitry in the other power domain.

In digital circuits, a level-shifter may receive one or more logic signals from circuitry operating at a first supply voltage and may output corresponding logic signals to circuitry operating at a second supply voltage different from the first. The second voltage swing may be greater than the first, or vice versa. For example, a level-shifter configured to receive logic signals from circuitry operating at a supply voltage of 3.3 volts could be configured to provide output logic signals to logic circuitry operating at 1.1 volts. Similarly, a level-shifter could be configured to receive signals from circuitry operating at 1.1 volts, and to provide output signals to circuitry operating at 3.3 volts. In addition to providing level-shifting functions, level-shifter circuits may also provide signals having either (or both) of a true logic state and/or a complementary logic state with respect to the input signals.

### SUMMARY

A level-shifting latch circuit is disclosed. In one embodiment, a level-shifting latch circuit combines the functionality of a level-shifter with the functionality of a latch circuit. The latch function may enable the level-shifting latch circuit to receive signals from another circuit (e.g., a dynamic logic circuit) during an evaluation phase, and to retain an output state during a next precharge phase. The state retention function may enable dynamic-to-static conversion of logic signals.

In one embodiment, a level-shifting latch circuit is coupled to receive first and second signals from a circuit operating in a first power domain. The circuit operating in the first power domain may include dynamic logic that drives the inputs of the level-shifting latch to a same logic level (e.g., a logic low) during a precharge phase. During a subsequent evaluation phase, one of the inputs of the level-shifting latch may transition to a complementary logic level (e.g., a logic high) while the other signal remains at the logic level to which it was driven during the precharge phase. The level-shifting latch may provide, to a circuit operating in a second power domain, an output signal corresponding to the input signal.

The level-shifting latch may include a first transistor stack configured to drive an internal node, and a second transistor stack configured to drive an output node. Each transistor stack may include an extra transistor. The extra transistors, working in tandem, may hold the state of the internal node and the output node (which is a complement of the state of the internal node) subsequent to the inputs being driven to the same logic level during the precharge phase of the next cycle.

Accordingly, various embodiments of the level-shifting latch circuit may provide a level-shifting function, a state retention function, and a dynamic-to-static conversion function, and may thus be used to couple dynamic logic in a first power domain to static logic in a second power domain.

### BRIEF DESCRIPTION OF THE DRAWINGS

The following detailed description makes reference to the accompanying drawings, which are now briefly described.

FIG. 1 is a block diagram of an integrated circuit (IC) having a memory operating according to a first supply voltage, a processor core operating according to a second supply voltage, and level-shifters coupled therebetween.

FIG. 2 is a block diagram of an IC having a dynamic logic circuit operating according to a first supply voltage and a static logic circuit operating according to a second supply voltage, and level-shifters coupled therebetween.

FIG. 3A is a schematic diagram of one embodiment of a level-shifting latch circuit.

FIG. 3B is a schematic diagram of another embodiment of a level-shifting latch circuit.

FIG. 4 is a flow diagram of illustrating a method of operating one embodiment of a level-shifting latch circuit.

FIG. 5 is a timing diagram illustrating the operation of one embodiment of a level-shifting latch circuit.

FIG. 6 is a block diagram of one embodiment of a system.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits and/or memory storing program instructions executable to implement the operation. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component.

### DETAILED DESCRIPTION OF EMBODIMENTS

### Integrated Circuit Embodiments

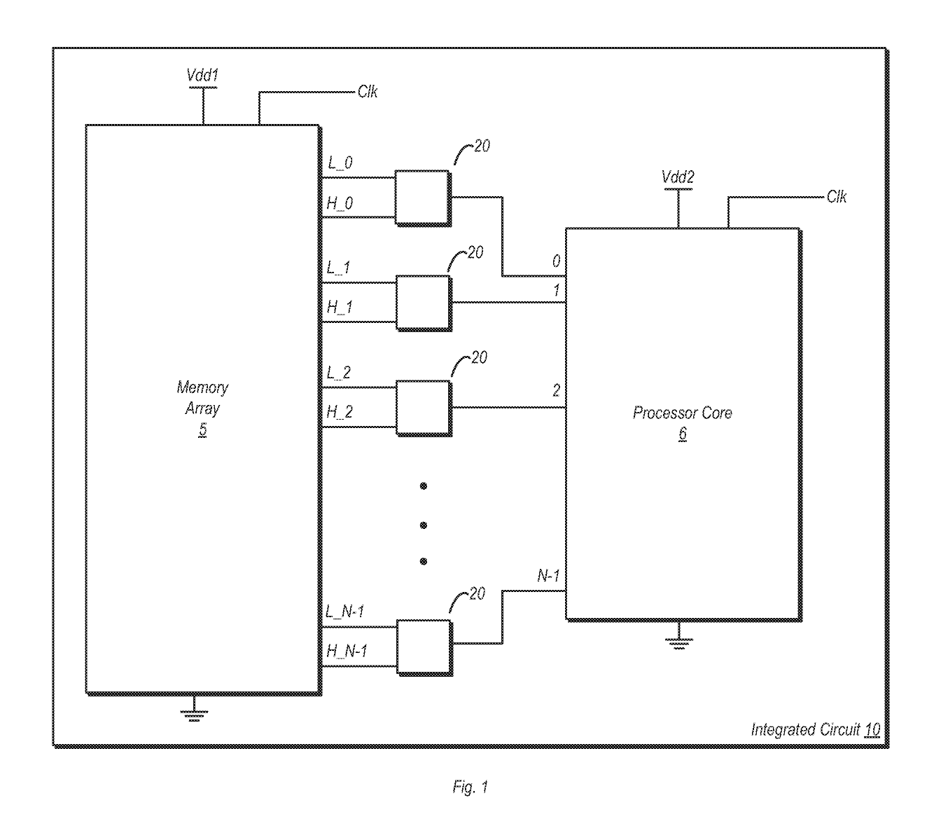

Turning now to FIG. 1, a block diagram of one embodiment of an integrated circuit (IC) is shown. In the embodiment shown, IC10 includes a memory array 5 coupled to receive a first supply voltage, Vdd1. IC 10 may also include a processor core 6 coupled to receive a second supply voltage, Vdd2. The second supply voltage may be different from the first supply voltage. For example, Vdd1 may be 2.2 volts, while Vdd2 may be 1.1 volts. These voltages are exemplary however, and can be any other voltage suitable for the circuits to which they are provided. Furthermore, Vdd1 may also be less than Vdd2 in some embodiments.

In the embodiment shown, memory array 5 is coupled to processor core 6 via read path passing through a number of level-shifting latches 20. Each of level-shifting latches 20 is coupled to receive a pair of input signals from memory array 5, and may provide a single-ended output signal to processor core 6. In an alternate embodiment, each level-shifting latch 20 may provide a dual-ended output signal. Processor core 6 may receive data (e.g., operands) from memory 5 during operation thorough the connections shown in the drawing. Although not explicitly shown here for the sake of simplicity, additional connections may be provided that enable processor core 6 to write information to memory array 5.

The input signals received by each level-shifting latch 20 in this embodiment, have a voltage swing that corresponds to Vdd1. The output signals provided by each level-shifting latch 20 to processor core 6 may have a voltage swing that corresponds to Vdd2. Accordingly, each level-shifting latch 20 in the embodiment shown is thus configured to provide a level shifting function.

Memory array 5 may include dynamic logic circuitry configured to generate and provide complementary signals to each level-shifting latch 20. A dynamic logic circuit may operate in two different phases, according to a cycle clock signal. During a first portion of the clock cycle (e.g., when the clock is low), the dynamic logic circuitry may perform a precharge or pre-discharge of certain nodes in the circuit. During a second portion of the clock cycle (e.g., when the clock is high), the dynamic logic circuitry may evaluate the inputs and cause one of the nodes that were pre-charged/pre-discharged to transition to a certain state. Using memory 5 as an example, the output signals of each pair (e.g., L_{—}0, H_{—}0; L_{—}1, H_{—}1, etc.) may be driven low during a precharge phase. During a subsequent evaluation phase, one of the two signals driven low may transition high, corresponding to data read from a bit cell of memory 5.

During the evaluation phase, each level-shifting latch 20 in the embodiment shown may generate an output signal that corresponds to the state of respectively received input signals. Moreover, each level-shifting latch 20 in the embodiment shown retain the state of the output signal after its respective input signals are both driven to the same logic state during a precharge phase of the next cycle. For example, if a given one of level-shifting latches 20 generates a high output signal responsive to inputs received during the evaluation phase, it may retain that state on its output during a subsequent precharge cycle in which both of its inputs are driven low. Thus, in addition to providing the level-shifting function noted above, each level-shifting latch 20 in the embodiment shown is also configured to provide at state retention function, and thus also provide dynamic-to-static conversion of logic signals.

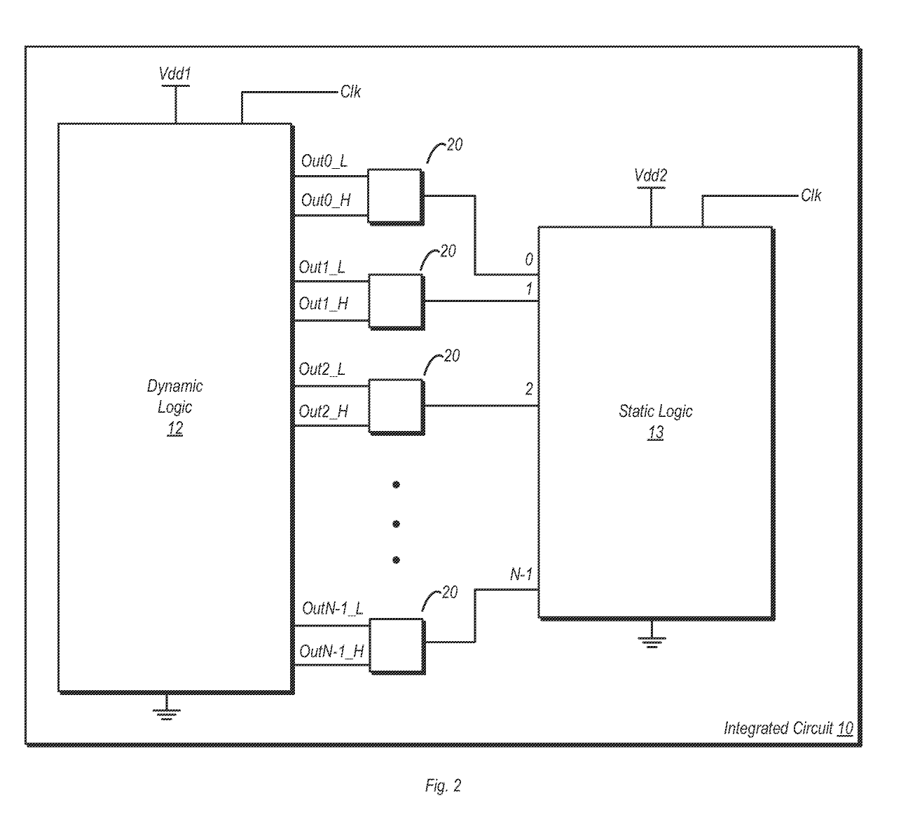

FIG. 2 is a block diagram of another embodiment of an IC 10. In the embodiment shown, dynamic logic 12 is coupled to receive the supply voltage Vdd1, while static logic 13 is coupled to receive the supply voltage Vdd2, which may be different from Vdd1. Signals may be conveyed from dynamic logic 12 to static logic 13 via the connections shown, each of which includes a level-shifting latch 20. Although not explicitly shown, additional connections enabling static logic 13 to convey signals to dynamic logic 12 may also be provided.

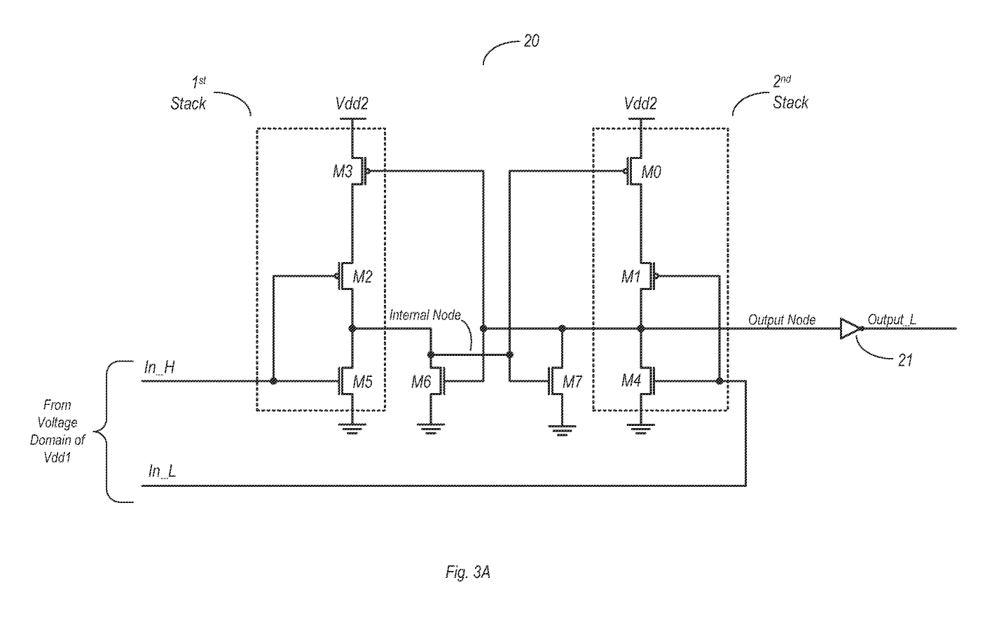

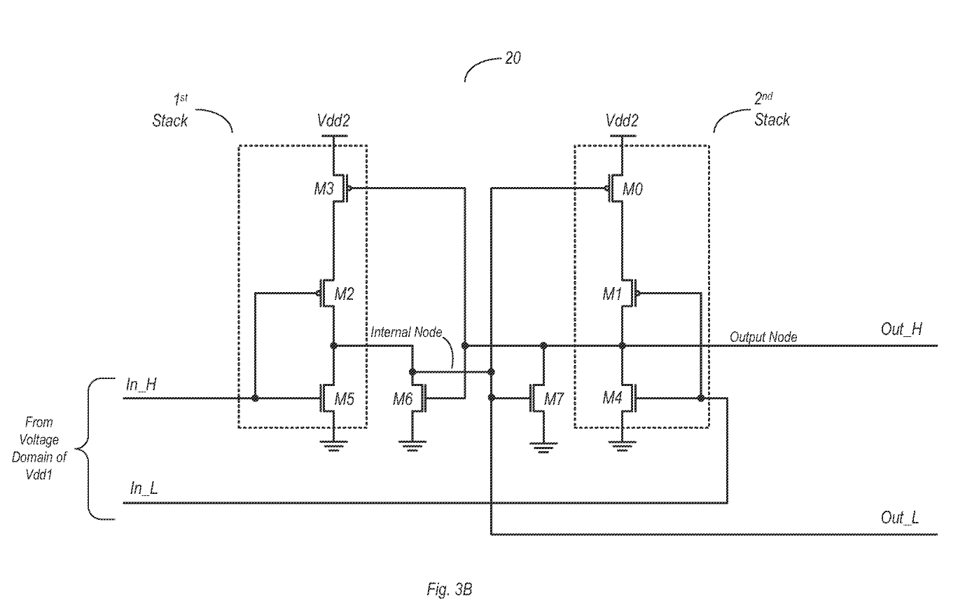

Similar to the embodiment discussed above with reference to FIG. 1, each level-shifting latch 20 may provide a level-shifting function, a state retention function, and a dynamic-to-static conversion function. Due to the functionality provided, various embodiments of level-shifting latch 20 may be suitable for providing signal pathways between dynamic and static logic circuits in different power domains. An embodiment of a circuit used to implement a level-shifting latch 20 will now be discussed in further detail with reference to FIG. 3.

### Level-Shifting Latch Circuit:

FIG. 3 is a schematic diagram illustrating one embodiment of a level-shifting latch circuit. In the embodiment shown, level-shifting latch 20 includes a first stack of transistors (M2, M3, and M5) and a second stack of transistors (M0, M1, and M4) arranged to perform a level-shifting function. Transistors M2 and M5 of the first stack are coupled to receive a first input signal, In_H from a power domain powered by Vdd1. Transistors M1 and M4 of the second stack are coupled to receive a second input signal, In_L, also from the power domain powered by Vdd1. Input signals received at In_H and In_L may each have a voltage swing that is commensurate with the supply voltage received in the power domain powered by Vdd1. On the other hand, an output signal provided on the output node of level-shifting latch 20 may have a voltage swing that is commensurate with the supply voltage in the power domain powered by Vdd2. Accordingly, level-shifting latch 20 may receive input signals from a first power domain operating at a first supply voltage and output signals to a second power domain operating at a second supply voltage.

In the embodiment shown, a gate terminal of transistor M3 is coupled to the output node, while the gate terminal of transistor M0 is coupled to an internal node. When In_H is a logic low, transistor M2 may be activated. When In_L is a logic high at the same time I_H is a logic low, transistor M4 may be activated. When activated, the output node may be pulled low through transistor M4. The low on the output node may in turn cause the activation of transistor M3. When M3 and M2 are both active at the same time, a pull-up path between the internal node and Vdd2 is provided. Thus, when In_H and In_L are at a logic low and a logic high, respectively, the output node of this embodiment may be driven low, while the internal node may be driven high.

When In_H is provided as a logic high, transistor M5 may be activated, while transistor M2 is held inactive. When In_L is provided as a logic low, transistor M1 may be activated, while transistor M4 may be held inactive. When transistor M5 is activated, the internal node may be pulled low, thereby activating transistor M0. Thus, if In_H is high while In_L is low, transistors M0 and M1 may be active at the same time, thereby providing a pull-up path between the output node and Vdd2. Accordingly, when In_H and In_L are at logic high and logic low levels, respectively, the internal node of the embodiment shown is driven low while the output node is pulled high.

In general, level-shifting latch 20 in the embodiment shown is configured such that for a pair of complementary input signals, the internal node and the output node are driven to complementary logic states. More particularly, the internal node in the embodiment shown is driven to the same state as In_L while the output node is driven to the same state as In_H when these two inputs are complements of each other.

It is noted that in embodiments where it is desirable to provide both the true and complementary outputs, the internal node of level-shifting latch 20 may also be coupled to provide an output signal. FIG. 3B illustrates one such embodiment, wherein the node designated as the output node may provide the output signal Out_H, while the node designated as the internal node may provide the output signal Out_L.

It is also noted that while an inverter 21 is shown coupled between the output node and Output_L node in the embodiment shown, embodiments utilizing a non-inverting buffer between these nodes is also possible and contemplated. Inverter 21 or an alternate non-inverting buffer included in the circuit in this manner may provide additional drive strength for signals that have higher fan out requirements.

Transistors M6 and M7 may enable level-shifting latch 20 to implement both a state retention function and a dynamic-to-static conversion function. As noted above, when In_H is provided as a logic high while In_L is provided as a logic low, the output node may be pulled high while the internal node may be pulled low. The logic high on the output node may in turn cause transistor M6 to activate, thereby providing another pull-down path between the internal node and ground. If In_H falls low again while In_L remains low (e.g., responsive to a precharge or pre-discharge of a dynamic circuit coupled to these node), transistor M6 may hold the low state of the internal node even after transistor M5 is no longer active. Transistor M0, with its gate coupled to the internal node, may thus remain active due to the logic low provided by the pull-down path of the active M6. Since In_L may also be low at this time, transistor M1 remains active, and thus the pull-up path between the output node and Vdd2 also remains. Therefore, the high on the output node may be retained during a precharge/pre-discharge phase for the next cycle of operation the circuit coupled to provide the signals to In_H and In_L

When In_L is provided as a logic high and In_L is provided as a logic low, the output node may be pulled low, while the internal node may be pulled high (through transistors M2 and M3). The high on the internal node may in turn cause the activation of transistor M7, thereby providing another pull-down path between the output node and ground. The low on the output node may hold transistor M3 in an active state, while, the low on In_H may hold M2 in an active state. When In_L falls low responsive to a pre-charge/pre-discharge of the circuit coupled to In_L and In_H (and while In_H remains low), transistor M7 may remain active, continuing to provide the pull-down path between the output node and ground. With transistor M7 remaining active, the pull-up path between the internal node and Vdd2 through transistors M2 and M3 also remains active. Therefore, level-shifting latch may retain the logic low on the output node during the precharge/pre-discharge phase for the next cycle of operation of the circuit coupled to provide the signals to In_H and In_L.

As previously noted, the circuit coupled to generate and provide the In_H and In_L signals may be a dynamic logic circuit. The dynamic logic circuit may function according to cycles having a precharge (or pre-discharge) phase and an evaluation phase. The In_H and In_L signals may be provided during the evaluation phase, responsive to their generation by the dynamic logic circuit. During the precharge phase of a subsequent cycle, these signals may be driven to the same logic value (e.g., a logic low). However, the output signal generated by level-shifting latch 20 responsive to the values of In_H and In_L during the evaluation phase of the previous cycle may be retained on the output node during the subsequent precharge phase, as described above, thus making the output signal a static logic signal. Thus, the state retention function provided by level-shifting latch 20 may also provide a dynamic-to-static conversion function. Furthermore, since level-shifting latch 20 may operate responsive to the signals received on In_H and In_L, it may thus be implemented without the need to receive a clock signal, thereby eliminating the need for extra circuitry and thus providing some power savings.

In the embodiment shown, transistors M0-M3 are NMOS (n-channel metal oxide semiconductor) transistors, while transistors M4-M7 are PMOS (p-channel metal oxide semiconductor) transistors. However, it is note that the implementation shown in FIG. 3 is not intended to be limiting, and thus different types of transistors may be used for any one of the devices shown. Furthermore, the reference to certain polarities and logic levels are also not intended to be limiting. Accordingly, level-shifting latch 20 in the embodiment shown is but one of many possible embodiments of a circuit that may provide and combine the functions of level-shifting, state retention, and dynamic-to-static conversion.

### Method for Operating a Level-Shifting Latch Circuit:

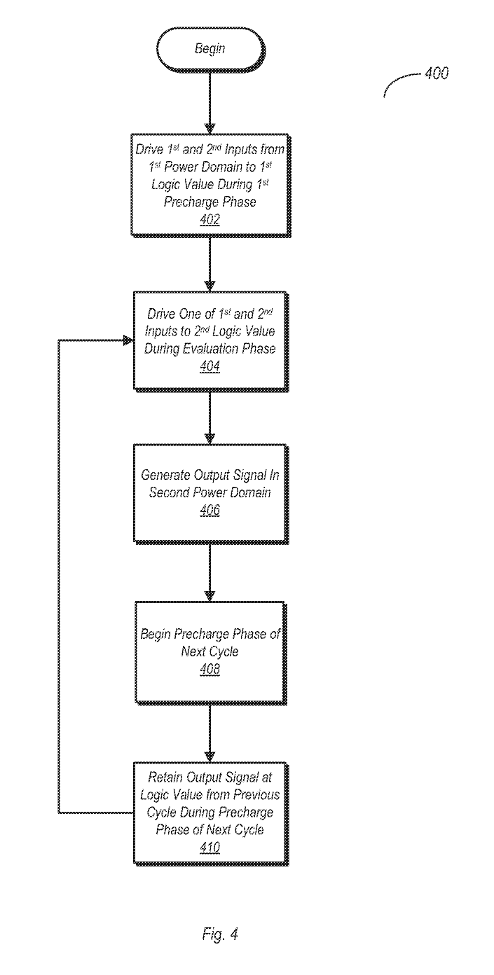

FIG. 4 is a flow diagram illustrating one embodiment of a method for operating a level-shifting latch. Method 400 may be directed to an embodiment of level-shifting latch 20 as discussed above. Furthermore, method 400 may be directed to an arrangement wherein the level-shifting latch is coupled to receive signals output from a dynamic logic circuit, and is configured to generate and coupled to provide a static logic signal to a static logic circuit.

Method 400 begins with a dynamic logic circuit in a first power domain driving first and second inputs of a level-shifting latch in a second power domain to a first logic value (e.g., logic low) during a precharge phase of the dynamic logic circuit (block 402). During an evaluation phase subsequent to the precharge phase, the dynamic logic circuit may evaluate its respective inputs such that one of the two inputs to the level-shifting latch is driven to a second logic value that is complementary with respect to the first logic value (block 404). The logic value of the other input of the level-shifting latch may remain at the first logic value.

Responsive to its input signals having complementary states, the level-shifting latch may generate an output signal that may be provided to a logic circuit in a second power domain (block 406). The operating voltage of the logic circuit in the second voltage domain may be different than the operating voltage of the dynamic logic circuit in the first power domain.

Upon conclusion of the evaluation phase, the dynamic circuit may transition to the next cycle of operation. The transition to the next cycle of operation may be marked by the beginning of another precharge phase (block 408). The inputs to the level-shifting latch may once again be driven to the first logic value responsive to the precharge operation in the dynamic logic circuit. However, the level-shifting latch may nevertheless retain the state of the output signal generated during the evaluation phase of the previous cycle (block 410). Following the precharge phase initiated in block 408, the method may transition to an evaluation phase in block 404, and repeat for each cycle of operation thereafter.

### Timing Diagram:

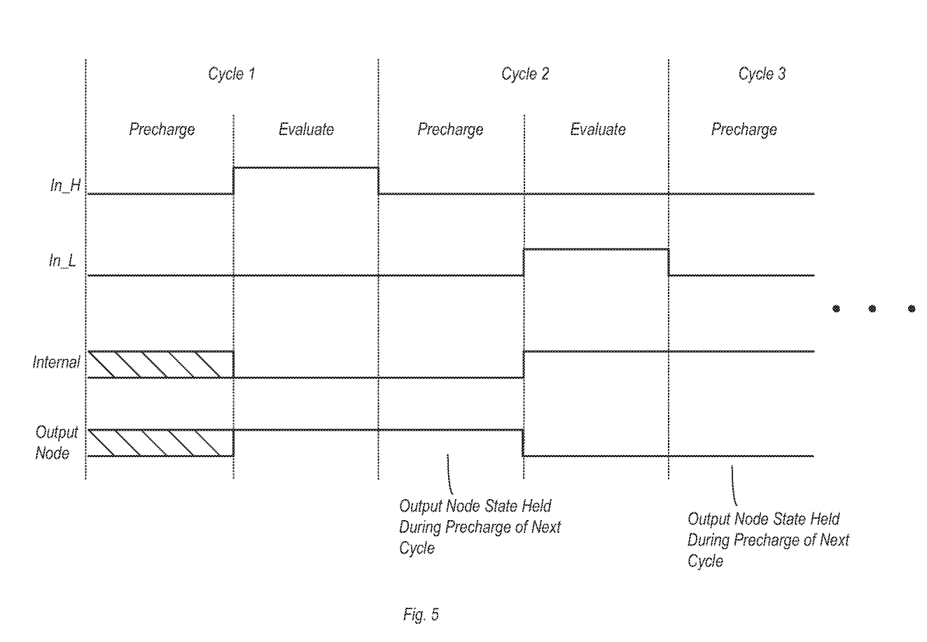

FIG. 5 is a timing diagram that further illustrates the operation of an embodiment of a level-shifting latch 20. During a precharge phase of cycle 1, both In_H and In_L are low, while the internal node and the output node are each held at their previous state. During the evaluation phase in cycle 1 of this example, In_H transitions high, while In_L remains low. Responsive to the transition high of In_H, the output node is high while the internal node is low.

During a precharge phase of a next cycle, cycle 2, the internal node is held low and the output node is held high, despite the fact that In_H is driven low once again (while In_L remains low). During the evaluation phase of cycle 2, In_L transitions high. The internal node follows In_L, while the output node falls low.

During the precharge phase of cycle 3, In_L falls low again, with In_H remaining low. However, the internal node is retained at a logic high, while the output node is retained at a logic low.

The exemplary operation illustrated in the timing diagram of FIG. 5 may continue on a cycle-by-cycle basis. During the precharge phase of each cycle, the level-shifting latch circuit may hold the previous state of its output node. During the evaluation phase of each cycle, the level-shifting latch circuit may respond to the input signals received on In_H and In_L, with the response reflected on the output node.

### Exemplary System:

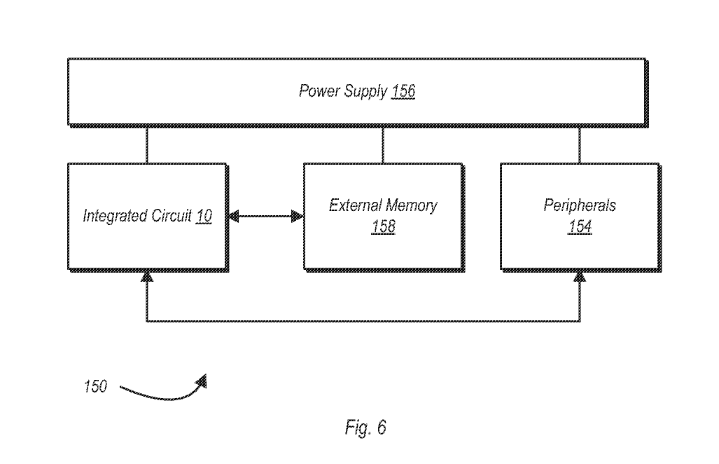

Turning next to FIG. 6, a block diagram of one embodiment of a system 150 is shown. In the illustrated embodiment, the system 150 includes at least one instance of an IC 10 (from FIG. 1) coupled to one or more peripherals 154 and an external memory 158. A power supply 156 is also provided which supplies the supply voltages to the IC10 as well as one or more supply voltages to the memory 158 and/or the peripherals 154. Thus, the power supply 156 may include the voltage regulator 18 shown in FIG. 1. In some embodiments, more than one instance of the IC10 may be included (and more than one external memory 158 may be included as well).

The peripherals 154 may include any desired circuitry, depending on the type of system 150. For example, in one embodiment, the system 150 may be a mobile device (e.g. personal digital assistant (PDA), smart phone, etc.) and the peripherals 154 may include devices for various types of wireless communication, such as wifi, Bluetooth, cellular, global positioning system, etc. The peripherals 154 may also include additional storage, including RAM storage, solid state storage, or disk storage. The peripherals 154 may include user interface devices such as a display screen, including touch display screens or multitouch display screens, keyboard or other input devices, microphones, speakers, etc. In other embodiments, the system 150 may be any type of computing system (e.g. desktop personal computer, laptop, workstation, net top etc.).

The external memory 158 may include any type of memory. For example, the external memory 158 may be SRAM, dynamic RAM (DRAM) such as synchronous DRAM (SDRAM), double data rate (DDR, DDR2, DDR3, etc.) SDRAM, RAMBUS DRAM, etc. The external memory 158 may include one or more memory modules to which the memory devices are mounted, such as single inline memory modules (SIMMs), dual inline memory modules (DIMMs), etc.

Numerous variations and modifications will become apparent to those skilled in the art once the above disclosure is fully appreciated. It is intended that the following claims be interpreted to embrace all such variations and modifications.

What is claimed is:

1. A circuit comprising:
a level-shifter circuit having an internal node and an output node, wherein the level-shifting circuit is configured to provide, on the output node, an output signal having a logic state that is determined by a first input signal and a second input signal during a time that the first input signal and second input signal have complementary logic states;
a first transistor coupled to the output node; and
a second transistor coupled to the internal node;
wherein the first and second transistors are configured to maintain the output node at a current logic state responsive to both the first and second input signals being driven to a same logic state.

2. The circuit as recited in claim 1, wherein the first transistor is configured to drive the output node to a low state responsive to the first input signal having a low state and the second input signal having a high state, and wherein the first transistor is configured to retain the output node at the low state subsequent to the second input signal transitioning to the low state concurrent with the first input signal remaining at the low state.

3. The circuit as recited in claim 1, wherein the second transistor is configured to drive the internal node to a low state responsive to the first input signal having a high state and the second input signal having a low state, wherein the second transistor is configured to retain the internal node at the low state subsequent to the first input signal transitioning to the low state concurrent with the second input signal remaining at the low state, and wherein the second transistor is configured to, when active, cause the output signal to retain a high state when both the first and second input signals are at the low state.

4. The circuit as recited in claim 1, wherein the level-shifter is configured to receive the first and second input signals from circuitry operating at a first supply voltage and is further configured to provide the output signal to circuitry operating at a second supply voltage that is different from the first supply voltage.

5. The circuit as recited in claim 1, wherein the first and second transistors are configured to cause the internal node to have a logic state that is complementary with respect to a logic state of the output node.

6. An integrated circuit comprising:
a first circuit configured to operate according to a first supply voltage;
a second circuit configured to operate according to a second supply voltage different from the first supply voltage; and
a level-shifter circuit coupled between the first circuit and the second circuit, wherein the level-shifter circuit is configured to receive first and second input signals from the first circuit and is configured to generate an output signal to the second circuit responsive to the first and second input signals;
wherein, during a evaluation phase of a first cycle, the first circuit is configured to provide first and second input signals to the level-shifter circuit, the first and second input signals having complementary logic states, and wherein the level-shifter circuit is configured to generate the output signal at a first logic state responsive to the first and second input signals; and
wherein, during a precharge phase of a subsequent cycle, the first circuit is configured to drive the first and second input signals to a same logic state, and wherein the level-shifter circuit is configured to maintain the output signal at the first logic state subsequent to the first circuit driving the first and second input signals to the equivalent logic state.

7. The integrated circuit as recited in claim 6, wherein the first circuit is a dynamic logic circuit, and wherein the second circuit is a static logic circuit.

8. The integrated circuit as recited in claim 6, wherein the first circuit is a memory, and wherein the second circuit is a processor core.

9. The integrated circuit as recited in claim 6, wherein the level-shifter circuit includes a first transistor coupled to the output node and a second transistor coupled to an internal node of the level-shifter circuit, wherein the first and second transistors are configured to cause the output signal to be maintained at the first logic state subsequent to the first circuit driving the first and second input signals to the equivalent logic state.

10. The integrated circuit as recited in claim 6, wherein the level-shifter circuit includes a first transistor coupled to the output node and a second transistor coupled to an internal node of the level-shifter circuit, wherein the first transistor is configured to, when active, drive the output node low, wherein the second transistor is configured to, when active, cause the output node to be driven high, and wherein the first and second transistors are configured to cause the internal node to be in a complementary logic state with respect to the output node.

11. A circuit comprising:
a first transistor stack including first and second transistors having respective gate terminals coupled to receive a first input signal, and a third transistor having a respective gate terminal coupled to an output node;
a second transistor stack including fourth and fifth transistors having respective gate terminals coupled to receive a second input signal, and a sixth transistor having a respective gate terminal coupled to an internal node;
a seventh transistor having a gate terminal coupled to the internal node, wherein the seventh transistor is configured to drive the output node to a first logic state responsive to the first input signal being at the first logic state and the second input signal being at the second logic state; and
an eighth transistor having a gate terminal coupled to the output node, wherein the eighth transistor is configured to drive the internal node to the first logic state responsive to the first logic signal being at the second logic state and the second input signal being at the first logic state.

12. The circuit as recited in claim 11, wherein the seventh transistor is configured to continue driving the output node to the first logic state after the first and second inputs signals transition to a same logic state subsequent to the first input signal being at the first logic state and the second input signal being at the second logic state.

13. The circuit as recited in claim 11, wherein the eighth transistor is configured to continue driving the internal node to the first logic state after the first and second input signals transition to a same logic state subsequent to the first input signal being at the second logic state and the second input signal being at the first logic state, and wherein the eighth transistor is configured to cause the output node to be held at the second logic state responsive to driving the internal node to the first logic state.

14. The circuit as recited in claim 11, wherein the first transistor stack is configured to provide a pull-up path between the internal node and a supply voltage node, through the first and third transistors, responsive to the first input signal having a logic low state and the second input signal having a logic high state, and wherein the first transistor stack is configured to cause the output node to be driven to a logic low state when the pull-up path is provided.

15. The circuit as recited in claim 11, wherein the second transistor stack is configured to provide a pull-up path between the output node and a supply voltage node, through the fourth and sixth transistors, responsive to the first input signal having a logic high state and the second input signal having a logic low state, wherein the second transistor stack is configured to cause the internal node to be driven to a logic low state when the pull-up path is provided.

16. A method comprising:
a first circuit driving first and second inputs of a level-shifting circuit to a first logic state during a precharge phase of a first cycle, wherein the first circuit is configured to operate at a first supply voltage;
driving one of the first and second inputs to a second logic state during an evaluation phase of the first cycle;
the level-shifter circuit generating an output signal responsive to one of the first and second inputs being driven to the second logic state, wherein the level-shifter circuit is coupled to provide the output signal to a second circuit operating at a second supply voltage different from the first supply voltage;
the first circuit driving the first and second inputs low responsive to a precharge phase of a next cycle; and
the level-shifting circuit maintaining a logic state of the output signal subsequent to the first circuit driving the first and second inputs low during the precharge phase of the next cycle.

17. The method as recited in claim 16, further comprising the level-shifting circuit providing the output signal at a logic high responsive to receiving a logic high on the first input and a logic low on the second input.

18. The method as recited in claim 17, further comprising the level-shifting circuit maintaining the logic high on the output signal subsequent to receiving a logic low on each of the first and second inputs during the precharge phase of the next cycle.

19. The method as recited in claim 16, further comprising the level-shifting circuit providing the output signal at a logic low responsive to receiving a logic low on the first input and a logic high on the second input.

20. The method as recited in claim 19, further comprising the level-shifting circuit maintaining the logic low on the output signal subsequent to receiving a logic low on each of the first and second inputs during the precharge phase of the next cycle.

21. A circuit comprising:
first and second p-channel metal oxide semiconductor (PMOS) transistors each having respective source terminals coupled to a voltage supply node;
a third PMOS transistor having a respective source terminal coupled to a drain terminal of the first PMOS transistor;
a fourth PMOS transistor having a respective source terminal coupled to a drain terminal of the second PMOS transistor;
first and second n-channel metal oxide semiconductor (NMOS) transistors having respective drain terminals coupled to a drain terminal of the third PMOS transistor, wherein gate terminals of the first NMOS and third PMOS transistors are coupled to a first input node; and
third and fourth NMOS transistors having respective drain terminals coupled to a drain terminal of the fourth PMOS transistor, wherein gate terminals of the fourth NMOS and fourth PMOS transistors are coupled to a second input node;
wherein the first and third PMOS transistors are configured to cause an output node to be driven low responsive to a logic low on the first input node and a logic high on the second input node;
wherein the second and fourth PMOS transistors are configured to cause the output node to be driven high responsive to a logic high on the first input node and a logic low on the second input node; and
wherein the second and third NMOS transistors are configured to cause the output node to maintain an output state subsequent to both the first and second input nodes falling low.

22. The circuit as recited in claim 21, further comprising a first functional circuit coupled to the first and second input nodes, and a second functional circuit coupled to the output node, wherein the first functional circuit is configured to receive a first supply voltage, wherein the second functional circuit is configured to receive a second supply voltage that is different from the first supply voltage.

23. The circuit as recited in claim 22, wherein the first functional circuit is a dynamic logic circuit and the second functional circuit is a static logic circuit.

24. The circuit as recited in claim 22, wherein the first functional circuit is a memory array, and wherein the second functional circuit is a processor.
